(19) United States
(12) Patent Application Publication
(10) Pub. No.: US 2026/0066017 A1
(43) Pub. Date: Mar. 5, 2026

(54) METHOD AND APPARATUS FOR FMA COMPUTATION WITH HIGH LINEARITY AND HIGH COMPUTATIONAL EFFICIENCY BASED ON MRAM-SRAM CELL

(71) Applicant: Electronics and Telecommunications Research Institute, Daejeon (KR)

(72) Inventor: Jin Ho HAN, Seoul (KR)

(73) Assignee: Electronics and Telecommunications Research Institute, Daejeon (KR)

(21) Appl. No.: 19/318,637

(22) Filed: Sep. 4, 2025

(30) Foreign Application Priority Data
Sep. 5, 2024 (KR) 10-2024-0120920
Aug. 22, 2025 (KR) 10-2025-0117314

(51) Int. Cl. G11C 27/00

(52) U.S. Cl. CPC G11C 27/005

(57) ABSTRACT

A computation apparatus includes: a plurality of nvSRAM cells; and a controller configured generating an artificial intelligence computation result per currents flowing through the nvSRAM cells, wherein each nvSRAM cell includes a first partial cell including: a differential circuit including first and second inverters; a first access transistor having a drain connected to the first output node; a second access transistor having a drain connected to the second output node; a first MRAM cell including a first selection transistor and a first magnetic tunnel junction connected in series between a CBL node and the first output node; and a second MRAM cell including a second selection transistor and a second magnetic tunnel junction connected in series between the CBL node and the second output node.

### CROSS-REFERENCE TO RELATED APPLICATION

This application claims the benefit of and priority to Korean Patent Application No. 10-2024-0120920, filed on Sep. 5, 2024 and 10-2025-0117314, filed on Aug. 22, 2025, the entire disclosure(s) of which are hereby incorporated herein by reference in its entirety.

### TECHNICAL FIELD

The present disclosure relates to a method and an apparatus for FMA computation with high linearity and high computational efficiency based on MRAM-SRAM cell.

### BACKGROUND

The following description simply provides only the background information related to the present embodiment without configuring the related art.

To support processing of artificial neural networks in various fields, an artificial intelligence processor with high power efficiency is required; to this end, an artificial intelligence processor employing a Non-Volatile Memory (NVM)-based Processing-In-Memory (PIM) architecture is being developed.

The artificial intelligence processor typically supports only artificial intelligence operations with 8-bit fixed-point data type, and therefore, a particular scheme is needed to perform floating-point operations using the 8-bit fixed-point operations.

Accordingly, a method of employing Magnetoresistive RAM (MRAM) in an NVM-based PIM architecture may be used for artificial intelligence operations. In this case, when MRAM is used as the NVM, leakage power may be reduced by cutting off power during idle periods; however, when performing a write operation in MRAM, a high current or a high voltage is required to change the state of the MRAM cells.

Also, the inefficiency of the NVM-based PIM is caused by the high latency and high power consumption of MRAM during write operations.

As a solution to the disadvantage of MRAM, a non-volatile Static Random Access Memory (nvSRAM) including MRAM and Static Random Access Memory (SRAM) may be used.

The nvSRAM is a type of memory that utilizes the complementary features of SRAM and NVM and may be regarded as a memory formed by combining a conventional 6-Transistor (6T) structured SRAM cell with an NVM cell.

The nvSRAM may perform low-power read and write operations using the 6T-structured SRAM cell and may also perform data storage and restoration operations using the NVM cell.

As one example of nvSRAM, a 7-Transistor 1-Resistor (7T1R) structured nvSRAM (i.e., 7T1R nvSRAM) performs read and write operations in the SRAM mode and performs storage and restoration operations in the MRAM mode.

FIG. 1 illustrates the structure of the 7T1R nvSRAM.

The 7T1R nvSRAM 100 of FIG. 1 may achieve high area efficiency, but there is a significant limitation in terms of computational accuracy.

When performing PIM operations for artificial intelligence computation in the 7T1R nvSRAM 100, the 6T SRAM cell 110 is powered off, and the BLL is set to a voltage corresponding to VDD.

Also, weights are stored as resistance values in the Magnetic Tunnel Junction (MTJ) cell 120, and during artificial intelligence computation, a weight is fed to an external artificial intelligence computation circuit in the form of a current value at the SL node based on an activation signal RWSL and the corresponding weight.

FIG. 2 illustrates a truth table of operations in the 7T1R nvSRAM, and FIG. 3 illustrates a MAC computation table related to the operation of the 7T1R nvSRAM.

As shown in the truth table of FIG. 2, when the weight W=0 (i.e., the MTJ 120 is in a high resistance state (HRS)) and the activation signal A (i.e., the RWSL signal) is 1, the current I_{HRS} flowing to the SL node should ideally be 0. However, in practice, even if the MTJ 120 is in a high resistance state, the resistance value of the MTJ 120 is not infinite but has a finite magnitude; therefore, the magnitude of I_{HRS} may not be negligible compared with the current I_{LRS} of the MTJ 120 in a low resistance state (LRS).

Accordingly, when the Tunnel MagnetoResistance (TMR) ratio is small (i.e., when the difference between I_{HRS} and I_{LRS} is relatively small), there is a drawback in that when the total current flowing to the SL node from the MTJs of a plurality of 7T1R nvSRAMs is measured during an artificial intelligence computation process, even if the measured current magnitude corresponds to 1*I_{LRS}, it is difficult to accurately determine whether the current magnitude represents the current generated from a single low resistance MTJ or a sum of currents generated from a plurality of high resistance MTJs (e.g., 3*I_{HRS}).

As shown in FIG. 3, a MAC value, which represents an example of a result of artificial intelligence computation, may be defined by a current measurement value lying between Min and Max. However, a problem arises in that deriving the result of artificial intelligence computation according to the current measurement value using the table of FIG. 3 may not match the actual result of artificial intelligence computation. This is because the distribution of current values corresponding to different MAC values may overlap among different MAC values.

Due to the drawback of the 7T1R nvSRAM, a problem arises in that the accuracy of an artificial intelligence algorithm performing artificial intelligence computation by measuring the current flowing to the SL node from a plurality of 7T1R nvSRAMs may be significantly degraded.

### SUMMARY

The present disclosure is primarily directed to providing a method and an apparatus for FMS computation with high linearity and high computational efficiency based on MRAM-SRAM cells.

The objects of the present disclosure are not limited to those particularly described hereinabove, and the above and other objects that the present disclosure can achieve will be clearly understood by those skilled in the art from the following detailed description.

According to at least one aspect, A computation apparatus comprising: a plurality of nvSRAM cells; and a controller configured to generate an artificial intelligence computation result according to currents flowing through the plurality of nvSRAM cells, wherein each nvSRAM cell comprises a first partial cell, and the first partial cell comprises: a differential circuit including a first inverter and a second inverter connected in parallel between a power supply voltage and a ground voltage, a first output node of the first inverter being connected to a second input node of the second inverter and a second output node of the second inverter being connected to a first input node of the first inverter; a first access transistor having a drain connected to the first output node; a second access transistor having a drain connected to the second output node; a first MRAM cell including a first selection transistor and a first magnetic tunnel junction connected in series between a CBL node and the first output node; and a second MRAM cell including a second selection transistor and a second magnetic tunnel junction connected in series between the CBL node and the second output node.

According to another aspect, the method for performing computation in a computation apparatus comprising a plurality of nvSRAM cells, wherein each nvSRAM cell comprises a first partial cell, and the first partial cell comprises a differential circuit including a first inverter and a second inverter connected in parallel between a power supply voltage and a ground voltage, a first output node of the first inverter being connected to a second input node of the second inverter and a second output node of the second inverter being connected to a first input node of the first inverter; a first access transistor having a drain connected to the first output node; a second access transistor having a drain connected to the second output node; a first MRAM cell including a first selection transistor and a first magnetic tunnel junction connected in series between a CBL node and the first output node; and a second MRAM cell including a second selection transistor and a second magnetic tunnel junction connected in series between the CBL node and the second output node, the method comprising: a first process of controlling current to flow through each of the plurality of nvSRAM cells for artificial intelligence computation; and a second process of generating the artificial intelligence computation result according to the respective currents flowing through the plurality of nvSRAM cells.

Due to high linearity according to an embodiment of the present disclosure, it is possible to significantly improve the accuracy of artificial intelligence computation while maintaining high power efficiency during nvSRAM PIM operation.

Also, by solving the problem related to computational accuracy, it becomes possible to design analog PIM based on nvSRAM cells for artificial intelligence computation, thereby providing the effect of achieving high power efficiency.

The effects of the present disclosure are not limited to those mentioned above, and other effects not mentioned will be apparent to those of ordinary skill in the art from the above description.

### BRIEF DESCRIPTION OF THE DRAWINGS

FIG. 1 illustrates the structure of a 7T1R nvSRAM.

FIG. 2 illustrates a truth table of operations in the 7T1R nvSRAM.

FIG. 3 illustrates a MAC computation table related to the operation of the 7T1R nvSRAM.

FIG. 4 is an exemplary functional block diagram illustrating a computation apparatus according to one embodiment of the present disclosure.

FIG. 5 illustrates the structure of a first partial cell.

FIG. 6A illustrates a truth table of operation in an 8T2R nvSRAM and the corresponding current values of a CBL node, and FIG. 6B illustrates a MAC computation table related to the operation of a computation apparatus 400 having an 8T2R nvSRAM structure.

FIG. 7 illustrates the structure of a 16T4R nvSRAM cell.

FIG. 8a illustrates the states of four MTJs after the step of setting MTJ values is completed in a 16T4R nvSRAM, and FIG. 8b illustrates a truth table of operation in the 16T4R nvSRAM and the corresponding current values.

FIG. 9 is a flowchart illustrating a computation method according to an embodiment of the present disclosure.

FIG. 10 is a block diagram illustrating an exemplary computing device that may be used to implement a method or an apparatus according to the present disclosure.

### DETAILED DESCRIPTION

Hereinafter, some exemplary embodiments of the present disclosure will be described in detail with reference to the accompanying drawings. In the following description, like reference numerals preferably designate like elements, although the elements are shown in different drawings. Further, in the following description of some embodiments, a detailed description of known functions and configurations incorporated therein will be omitted for the purpose of clarity and for brevity.

Additionally, various terms such as first, second, A, B, (a), (b), etc., are used solely to differentiate one component from the other but not to imply or suggest the substances, order, or sequence of the components. Throughout this specification, when a part ‘includes’ or ‘comprises’ a component, the part is meant to further include other components, not to exclude thereof unless specifically stated to the contrary. The terms such as ‘unit’, ‘module’, and the like refer to one or more units for processing at least one function or operation, which may be implemented by hardware, software, or a combination thereof.

The following detailed description, together with the accompanying drawings, is intended to describe exemplary embodiments of the present invention, and is not intended to represent the only embodiments in which the present invention may be practiced.

FIG. 4 is an exemplary functional block diagram illustrating a computation apparatus according to one embodiment of the present disclosure.

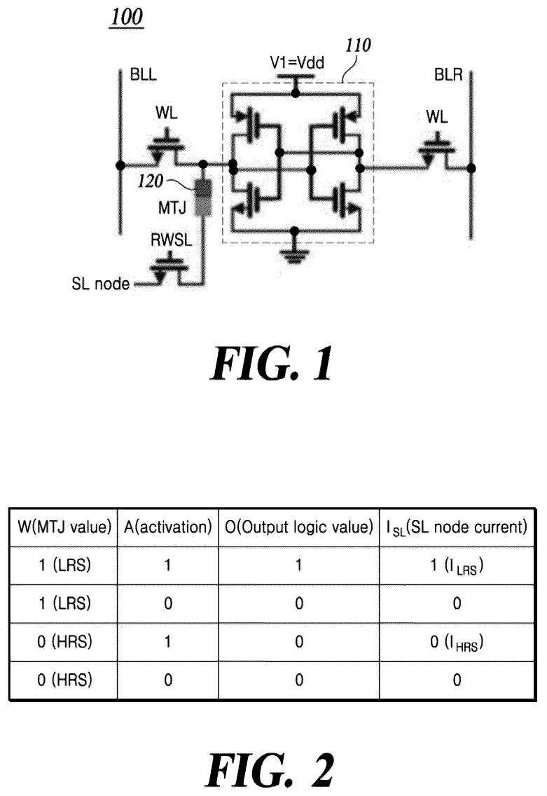

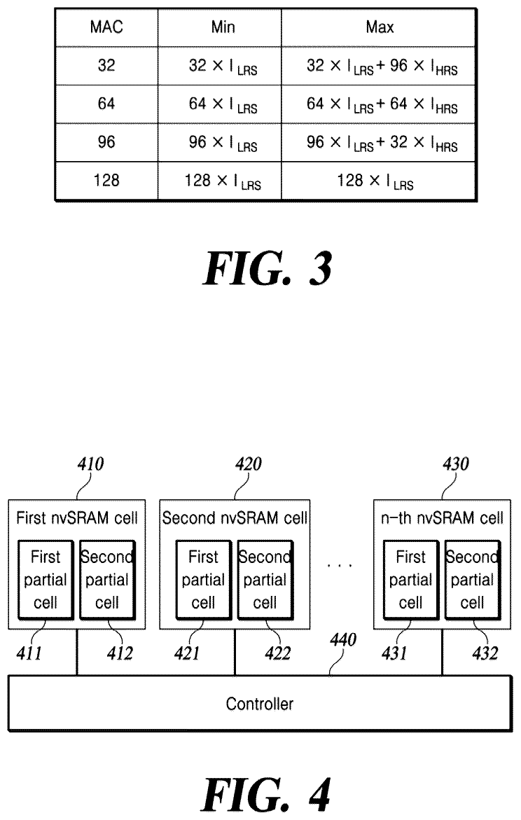

A computation apparatus 400 according to one embodiment of the present disclosure may be implemented to include a plurality of nvSRAM cells 410, 420, 430, and a controller 440. The computation apparatus 400 according to the present embodiment may be implemented by omitting part of the constituting elements of FIG. 1 or by additionally including other constituting elements not illustrated in FIG. 1.

Each of the nvSRAM cells 410, 420, 430 includes a first partial cell 411, 421, 431 and a second partial cell 412, 422, 432.

According to embodiments, each of the nvSRAM cells 410, 420, 430 may be implemented not as two partial cells but as a single partial cell (e.g., the first partial cell 411, 421, 431).

The controller 440 generates an artificial intelligence computation result according to the values of currents flowing from a plurality of nvSRAM cells 410, 420, 430.

Each of the first partial cells 411, 421, 31 within each of the nvSRAM cells 410, 420, 430 is implemented to have an identical structure.

In what follows, the operation of a plurality of nvSRAM cells 410, 420, 430 will be described focusing on the operation of one first partial cell 411.

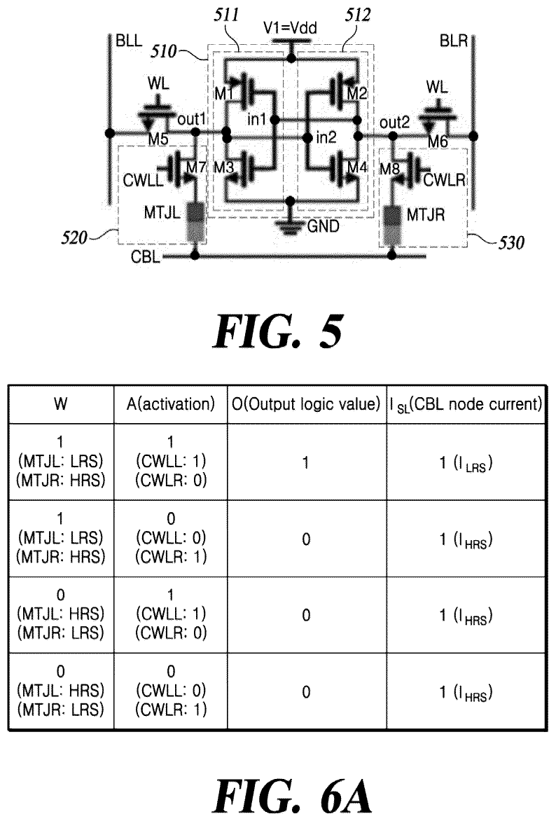

FIG. 5 illustrates the structure of a first partial cell.

The first partial cell 411 includes a differential circuit 510, a first access transistor M5, a second access transistor M6, a first MRAM cell 520, and a second MRAM cell 530.

The differential circuit 510 includes a first inverter 511 and a second inverter 512 connected in parallel between a supply voltage Vdd and a ground voltage GND.

A first output node out1 of the first inverter 511 is connected to a second input node in2 of the second inverter 512, and a second output node out2 of the second inverter 512 is connected to a first input node in1 of the first inverter 511.

The first inverter 511 includes a first pull-up transistor M1 and a first pull-down transistor M3 that are serially connected between a supply voltage and a ground voltage.

The gate of the first pull-up transistor M1 and the gate of the first pull-down transistor M3 are connected to form a first input node in1, and a junction formed by connecting the drain of the first pull-up transistor M1 and the drain of the first pull-down transistor M3 forms a first output node out1.

The source of the first pull-up transistor M1 is connected to the supply voltage, and the source of the first pull-down transistor M3 is connected to the ground voltage.

The second inverter 512 includes a second pull-up transistor M2 and a second pull-down transistor M4 that are serially connected between the supply voltage and the ground voltage.

The gate of the second pull-up transistor M2 and the gate of the second pull-down transistor M4 are connected to form a second input node in2, and a junction formed by connecting the drain of the second pull-up transistor M2 and the drain of the second pull-down transistor M4 forms a second output node out2.

The source of the second pull-up transistor M2 is connected to the supply voltage, and the source of the second pull-down transistor M4 is connected to the ground voltage.

The drain of the first access transistor M5 is connected to the first output node out1.

The drain of the second access transistor M6 is connected to the second output node out2.

A write signal BLL is input to the source of the first access transistor M5; a complementary write signal BLR is input to the source of the second access transistor M6; and the gate of the first access transistor M5 and the gate of the second access transistor M6 are connected to a common word line WL, respectively.

Here, the write signal BLL and the complementary write signal BLR have complementary values. For example, when the write signal BLL corresponds to logic value 1, the complementary write signal BLR corresponds to logic value 0, and when the write signal BLL corresponds to logic value 0, the complementary write signal BLR corresponds to logic value 1.

The first MRAM cell 520 includes a first selection transistor M7 and a first MTJL. The first selection transistor M7 and the first MTJL are connected in series between both ends of the first MRAM cell 520. One end of the first MRAM cell 520 is connected to the first output node out1, and the other end of the first MRAM cell 520 is connected to the CBL node.

The second MRAM cell 530 includes a second selection transistor M8 and a second MTJR. The second selection transistor M7 and the second MTJL are connected in series between both ends of the second MRAM cell 520. One end of the second MRAM cell 530 is connected to the second output node out2, and the other end of the second MRAM cell 530 is connected to the CBL node.

The Magnetic Tunnel Junction (MTJ), which implements the first Magnetic Tunnel Junction MTJL and the second Magnetic Tunnel Junction MTJR, is a device composed of a fixed magnetic layer, a tunnel insulating layer, and a free magnetic layer; when a high current flows from the fixed magnetic layer to the free magnetic layer, the MTJ enters a low resistance state, while when a high current flows from the free magnetic layer to the fixed magnetic layer, the MTJ enters a high resistance state.

The controller 440 includes a current circuit capable of detecting a summed current value obtained by adding respective current values flowing from the respective CBL nodes of the plurality of nvSRAM cells 410, 420, 430. The controller 440 generates an artificial intelligence computation result based on the summed current value.

The process in which the controller 440 receives data from an external module and performs write operations on the MTJL and MTJR according to the received data may be divided into a step of setting an output node value and a step of setting an MTJ value, as follows.

The setting of the output node value corresponds to the step of setting values at the first output node out1 and the second output node out2 of the differential circuit 510 according to the received data.

In the setting of the output node value, the controller 440 inputs OFF signals to the gate of the first selection transistor M7 (i.e., CWLL signal) and the gate of the second selection transistor M8 (i.e., CWLR signal), respectively; inputs ON signals to the gate of the first access transistor M5 and the gate of the second access transistor M6, respectively; and inputs a write signal to the source of the first access transistor M5 and inputs a complementary write signal to the source of the second access transistor M6, respectively, thereby forming a first output value at the first output node out1 based on the write signal and forming a second output value at the second output node out2 based on the complementary write signal.

Here, the write signal BLL may be applied as a voltage level and has a voltage level of Vdd (e.g., 4V or 5V) or a voltage level of GND that is complementary to Vdd. When the write signal BLL is Vdd, the complementary write signal BLR becomes GND, which is complementary to Vdd, while when the write signal BLL is GND, the complementary write signal BLR becomes Vdd, which is complementary to GND.

Also, in some embodiments, the write signal may be a relatively high voltage (e.g., Vdd/2+ΔV) or a relatively low voltage complementary to the relatively high voltage (e.g., Vdd/2−ΔV). When the write signal BLL is Vdd/2+ΔV, the complementary write signal BLR becomes Vdd/2−ΔV, which is complementary to Vdd/2+ΔV, while when the write signal BLL is Vdd/2−ΔV, the complementary write signal BLR becomes Vdd/2+ΔV, which is complementary to Vdd/2−ΔV. Here, ΔV may vary depending on the embodiments.

The setting of the MTJ value corresponds to the step of setting the first output value of the first output node out1 and the second output value of the second output node out2 to the MTJL and MTJR, respectively.

In the setting of the MTJ value, the controller 440 inputs ON signals (i.e., CWLL signal=ON, CWLR signal=ON) to the gates of the first selection transistor M7 and the second selection transistor M8, respectively; inputs OFF signals to the gates of the first access transistor M5 and the second access transistor M6, respectively; and when the first voltage and the second voltage are alternately applied to the CBL node at intervals longer than a predetermined time, complementary resistance states are formed in the MTJL and the MTJR based on the first output value and the second output value. Here, the first voltage and the second voltage refer to voltages of complementary levels; when the first voltage is a low voltage (e.g., 0V), the second voltage is a high voltage (e.g., Vdd), while when the first voltage is a high voltage, the second voltage is a low voltage.

The setting of the MTJ value operates according to the following two steps (i.e., a first step and a second step).
First step: The controller 440 performs the operation of setting a first step. The setting of the first step includes inputting ON signals (i.e., CWLL signal=ON, CWLR signal=ON) to the gates of the first selection transistor M7 and the second selection transistor M8, respectively; inputting OFF signals to the gates of the first access transistor M5 and the second access transistor M6, respectively; and applying a first voltage (e.g., a low voltage of 0V) to the CBL node. When the setting of the first step is performed, a resistance state indicating the corresponding output value is formed in one of the two MTJs between MTJL and MTJR.

When the setting of the first step is performed and the first output node out1 is in a state corresponding to logic value 1 (e.g., a high voltage Vdd state), a high current flows from the first output node out1 toward the CBL node through the first MRAM cell 520 due to a high voltage potential difference between the first output node out1 and the CBL node, and the MTJL in the first MRAM cell 520 enters a low resistance state due to the high current.

When the first output node out1 is in a state corresponding to logic value 1, the second output node out2 is complementarily in a state corresponding to logic value 0 (e.g., 0V state). Therefore, when the setting of the first step is performed, a potential difference sufficient to cause a high current to flow through the second MRAM cell 530 is not generated between the second output node out2 and the CBL node; therefore, the state of the MTJR in the second MRAM cell 530 is maintained in its previous state. At this time, the previous state of the MTJR may be either a high resistance state or a low resistance state.

When the setting of the first step is performed and the first output node out1 is in a state corresponding to logic value 0 (i.e., a low voltage 0V state), a potential difference sufficient to cause a high current to flow through the first MRAM cell 520 is not generated between the first output node out1 and the CBL node; therefore, the state of the MTJL is maintained in its previous state. At this time, the previous state of the MTJL may be either a high resistance state or a low resistance state.

When the first output node out1 is in the 0 state, the second output node out2 is complementarily in a state corresponding to logic value 1. Therefore, when the setting of the first step is performed, a high current flows from the second output node out2 toward the CBL node through the second MRAM cell 530 due to the high voltage potential difference between the second output node out2 and the CBL node, and the MTJR enters a low resistance state due to the high current.

As described above, as a result of performing the first step, the first voltage (e.g., a low voltage of 0V) is applied to the CBL node, and a resistance state indicating the corresponding output value is formed in one of the two MTJs between MTJL and MTJR.
Second step: The controller 440 performs the operation of setting a second step. The setting of the second step includes applying a second voltage (i.e., a high voltage Vdd) having a complementary level to the first voltage to the CBL node after a low resistance state is formed in one of the MTJs between the MTJL or the MTJR by the operation of the first step. In this case, the controller 440 performs the setting of the second step by maintaining the ON signals for the gates of the first selection transistor M7 and the second selection transistor M8 and the OFF signals for the gates of the first access transistor M5 and the second access transistor M6 in their previous input states.

When the setting of the second step is performed and the first output node out1 is in a state corresponding to logic value 1 (e.g., a high voltage Vdd state), a potential difference sufficient to cause a high current to flow through the first MRAM cell 520 is not generated between the first output node out1 and the CBL node; therefore, the state of the MTJL is maintained in its previous state.

When the first output node out1 is in a state corresponding to logic value 1, the second output node out2 enters a complementary state corresponding to logic value 0 (e.g., 0V state). Therefore, when the setting of the second step is performed, a potential difference sufficient to cause a high current to flow from the CBL node toward the second output node out2 is generated in the second MRAM cell 530.

Accordingly, when the setting of the second step is performed, a reverse high current flows into the second MRAM cell 530 due to the high voltage between the second output node out2 and the CBL node, and the MTJR within the second MRAM cell 530 enters a high resistance state due to the high current.

When the first output node out1 is in a state corresponding to logic value 0 (e.g., 0V state), a potential difference between the first output node out1 and the CBL node sufficient to cause a high current to flow from the CBL node toward the first output node out1 is generated in the first MRAM cell 520.

Accordingly, a reverse high current flows into the first MRAM cell 520 due to the high voltage between the first output node out1 and the CBL node, and the MTJL within the first MRAM cell 520 enters a high resistance state due to the high current.

As described above, in the second step, when the second voltage (e.g., a high voltage) is applied to the CBL node, one of the MTJs between the MTJL and the MTJR enters a high resistance state indicating the corresponding output value, thereby completing the second step and consequently completing the setting of the MTJ value.

After the setting of the MTJ value is completed, the computation apparatus 400 enters a state in which artificial intelligence computation may be performed.

The controller 440 obtains operation data corresponding to each nvSRAM cell 410, 420, 430 from the corresponding external module. The operation data includes an activation signal required for artificial intelligence computation.

When receiving the operation data, the controller 440 inputs ON signals to the gates of the first access transistor M5 and the second access transistor M6, respectively, and, based on the operation data, inputs signals with complementary values to the gate of the first selection transistor M7 (i.e., CWLL signal input terminal) and the gate of the second selection transistor M8 (i.e., CWLR signal input terminal). For example, when the operation data of the corresponding nvSRAM cell 410, 420, 430 is logic value 1, the controller 440 inputs an ON signal to the gate of the first selection transistor M7 and an OFF signal to the gate of the second selection transistor M8 in the corresponding nvSRAM cell 410, 420, 430. Also, when the operation data of the corresponding nvSRAM cell 410, 420, 430 is logic value 0, the controller 440 inputs an OFF signal to the gate of the first selection transistor M7 and an ON signal to the gate of the second selection transistor M8 in the corresponding nvSRAM cell 410, 420, 430. At this time, the controller 440 measures the current flowing from the CBL node of each nvSRAM cell 410, 420, 430 and generates an artificial intelligence computation result according to the measured current value.

Here, when a high current flows through the first MRAM cell 520 or the second MRAM cell 530 (i.e., when the MTJ of the first MRAM cell 520 or the second MRAM cell 530 is in a low resistance state (LRS)), the current is referred to as I_{LRS}; when a low current flows through the first MRAM cell 520 or the second MRAM cell 530 (i.e., when the MTJ of the first MRAM cell 520 or the second MRAM cell 530 is in a high resistance state (HRS)), the current is referred to as I_{HRS}.

The controller 440 receives currents from the plurality of nvSRAM cells 410, 420, 430, and generates an artificial intelligence computation result according to the magnitude of each received current.

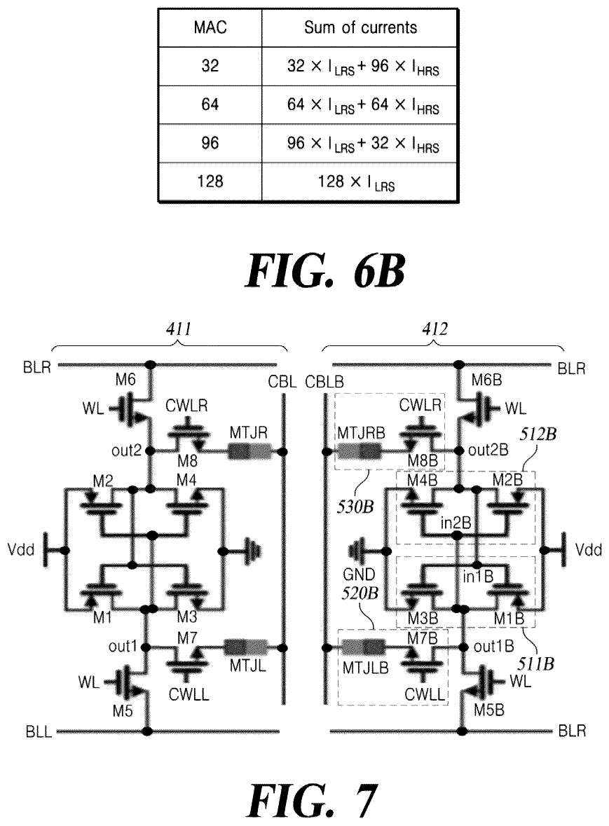

FIG. 6A illustrates a truth table of operation in an 8T2R nvSRAM and the corresponding current values of a CBL node, and FIG. 6B illustrates a MAC computation table related to the operation of a computation apparatus 400 having an 8T2R nvSRAM structure.

In FIG. 6A, W denotes the resistance states of two MTJs and the corresponding logic values, A denotes the input value of the activation signal, and O denotes the result of the computation A×W. Also, I_{CBL} denotes the current flowing from the CBL node.

As shown in FIG. 6A, when O (output logic value) is 1, I_{CBL} becomes I_{LRS}, and when O (output logic value) is 0, I_{CBL} becomes I_{HRS}. Therefore, unlike the 7T1R structure, the 8T2R structure does not exhibit ambiguity in the value of I_{CBL} when O (output logic value) is 0. Accordingly, in the 8T2R nvSRAM structure, errors in the MAC results that occur in the artificial intelligence computation employing the 7T1R nvSRAM may be eliminated.

The controller 440 receives current from each CBL node of the plurality of nvSRAM cells 410, 420, 430, respectively.

The controller 440 may generate an artificial intelligence computation result by summing the magnitudes of the received currents, but according to an embodiment, a voltage conversion circuit that converts the received current into voltage may also be used. In this case, the controller 440 generates the artificial intelligence computation result according to the magnitude of the cumulative voltage detected by the voltage conversion circuit.

In the ideal case, the cumulative voltage by the currents from the plurality of nvSRAM cells 410, 420, 430 should increase linearly in proportion to the number of nvSRAM cells 410, 420, 430 activated by an activation signal.

However, during artificial intelligence computation, as the number of nvSRAM cells 410, 420, 430 activated by the respective activation signals increases (i.e., as the resultant computation value increases), the activated nvSRAM cells 410, 420, 430 are interconnected in parallel. As the number of activated nvSRAM cells 410, 420, 430 increases, the composite resistance of the plurality of nvSRAM cells 410, 420, 430 interconnected in parallel decreases, thereby affecting the magnitude of the voltage detected by the voltage conversion circuit.

As a result, as the resultant computation value increases, the number of activated nvSRAM cells 410, 420, 430 also increases, and consequently, nonlinearity may be introduced into the artificial intelligence computation result generated according to the variation in the number of activated nvSRAM cells 410, 420, 430.

To overcome the drawback above, the computation apparatus 400 may be implemented based on the 16T4R nvSRAM structure.

FIG. 7 illustrates the structure of a 16T4R nvSRAM cell.

FIG. 7 illustrates a case in which each nvSRAM cell 410, 420, 430 is implemented to include both the first partial cell 411, 421, 431 and the second partial cell 412, 422, 432.

For the 16T4R nvSRAM cell structure, the first nvSRAM cell 410 including the first partial cell 411 and the second partial cell 412 will be described as an example.

The first nvSRAM cell 410 of FIG. 7 includes the first partial cell 411 and the second partial cell 412 described in FIG. 5. The second partial cell 412 employs the same components and connection relationships as the first partial cell 411.

The second partial cell 412 includes a second differential circuit including a 1B inverter 511B and a 2B inverter 512B, a 1B access transistor M5B, a 2B access transistor M6B, a 1B MRAM cell 520B, and a 2B MRAM cell 530B.

The 1B inverter 511B and the 2B inverter 512B are connected in parallel between a supply voltage Vdd and a ground voltage GND.

A 1B output node out1B of the 1B inverter 511B is connected to a 2B input node in2B of the 2B inverter 512B, and a 2B output node out2B of the 2B inverter 512B is connected to a 1B input node in1B of the 1B inverter 511B.

The 1B inverter 511B includes a 1B pull-up transistor M1B and a 1B pull-down transistor M3B connected in series between the supply voltage and the ground voltage.

The gates of the 1B pull-up transistor M1B and the 1B pull-down transistor M3B are connected together to form the 1B input node in1B, and a junction formed by connecting the drains of the 1B pull-up transistor M1B and the 1B pull-down transistor M3B forms the 1B output node out1B.

The source of the 1B pull-up transistor M1B is connected to the supply voltage, and the source of the 1B pull-down transistor M3B is connected to the ground voltage.

The 2B inverter 512B includes a 2B pull-up transistor M2B and a 2B pull-down transistor M4B connected in series between the supply voltage and the ground voltage.

The gates of the 2B pull-up transistor M2B and the 2B pull-down transistor M4B are connected together to form the 2B input node in2B, and a junction formed by connecting the drains of the 2B pull-up transistor M2B and the 2B pull-down transistor M4B forms the 2B output node out2B.

The source of the 2B pull-up transistor M2B is connected to the supply voltage, and the source of the 2B pull-down transistor M4B is connected to the ground voltage.

The drain of the 1B access transistor M5B is connected to the 1B output node out1B.

The drain of the 2B access transistor M6B is connected to the 2B output node out2B.

A complementary write signal BLR is input to the source of the 1B access transistor M5B, a write signal BLL is input to the source of the 2B access transistor M6B, and the gates of the 1B access transistor M5B and the 2B access transistor M6B are connected to a common word line WL.

The 1B MRAM cell 520B includes a 1B selection transistor M7B and a 1B magnetic tunnel junction device MTJLB. Between both ends of the 1B MRAM cell 520B, the 1B selection transistor M7B and the 1B magnetic tunnel junction device MTJLB are connected in series. One end of the 1B MRAM cell 520B is connected to the 1B output node out1B, and the other end of the 1B MRAM cell 520B is connected to the CBLB node.

The 2B MRAM cell 530B includes a 2B selection transistor M8B and a 2B magnetic tunnel junction device MTJRB. Between both ends of the 2B MRAM cell 530B, the 2B selection transistor M8B and the 2B magnetic tunnel junction device MTJRB are connected in series. One end of the 2B MRAM cell 530B is connected to the 2B output node out2B, and the other end of the 2B MRAM cell 530B is connected to the CBLB node.

The process in which the controller 440 receives data from an external module and performs a write operation on MTJL, MTJR, MTJLB, and MTJRB according to the received data includes setting an output node value and setting an MTJ value.

In FIG. 7, regarding the setting of the output node value and the setting of the MTJ value in the 16T4R nvSRAM cells 410, 420, 430, the operation of the first partial cell 411 is the same as the operation of the 8T2R nvSRAM cells 410, 420, 430 shown in FIG. 5; therefore, a detailed description of the operation of the first partial cell 411 in FIG. 7 will be omitted.

The setting of the output node value is a step of setting respective values to the 1B output node out1B and the 2B output node out2B according to the data received from the external module.

In the setting of the output node value, the controller 440 inputs OFF signals to the gate of the 1B selection transistor M7B (i.e., CWLL signal) and the gate of the 2B selection transistor M8B (i.e., CWLR signal), respectively; inputs ON signals to the gate of the 1B access transistor M5B and the gate of the 2B access transistor M6B, respectively; and inputs a complementary write signal to the source of the 1B access transistor M5B and inputs a write signal to the source of the 2B access transistor M6B, respectively, thereby forming a 1B output value at the 1B output node out1B based on the complementary write signal and forming a 2B output value at the 2B output node out2B based on the write signal.

When the setting of the output node value is completed, the controller 440 may perform the setting of the MTJ value.

In the setting of the MTJ value, the controller 440 may set the value of the 1B output node out1B and the value of the 2B output node out2B to MTJLB and MTJRB, respectively.

In the setting of the MTJ value, when the controller 440 inputs ON signals to the gates of the 1B selection transistor M7B and the 2B selection transistor M8B, inputs OFF signals to the gates of the 1B access transistor M5B and the 2B access transistor M6B, and alternately inputs the first voltage and the second voltage to the CBLB node at an interval equal to or greater than a predetermined interval, complementary resistance states are formed in MTJLB and MTJRB according to the 1B output value and the 2B output value.

The setting of the MTJ value is performed in the following two steps (i.e., a first step and a second step).
First step: In the setting of the first step, the controller 440 applies ON signals (i.e., CWLL signal=ON, CWLR signal=ON) to the gates of the 1B selection transistor M7B and the 2B selection transistor M8B, applies OFF signals to the gates of the 1B access transistor M5B and the 2B access transistor M6B, and applies a first voltage (e.g., a low voltage of 0 V) to the CBLB node. When the setting of the first step is performed, a resistance state indicating the corresponding output value is formed in one of the two MTJs between MTJLB and MTJRB.

When the setting of the first step is performed and the 1B output node out1B is in a state corresponding to logic value 1 (e.g., a high voltage Vdd state), a high current flows from the 1B output node out1B toward the CBLB node through the 1B MRAM cell 520B due to a high voltage potential difference between the 1B output node out1B and the CBLB node, and the MTJLB in the 1B MRAM cell 520B enters a low resistance state due to the high current.

When the 1B output node out1B is in a state corresponding to logic value 1, the 2B output node out2B is complementarily in a state corresponding to logic value 0 (e.g., 0V state). Therefore, when the setting of the first step is performed, a potential difference sufficient to cause a high current to flow through the 2B MRAM cell 530B is not generated between the 2B output node out2B and the CBLB node; therefore, the state of the MTJRB in the 2B MRAM cell 530B is maintained in its previous state. At this time, the previous state of the MTJRB may be either a high resistance state or a low resistance state.

When the setting of the first step is performed and the 1B output node out1B is in a state corresponding to logic value 0 (i.e., a low voltage 0V state), a potential difference sufficient to cause a high current to flow through the 1B MRAM cell 520B is not generated between the 1B output node out1B and the CBLB node; therefore, the state of the MTJLB is maintained in its previous state. At this time, the previous state of the MTJLB may be either a high resistance state or a low resistance state.

When the 1B output node out1B is in the state corresponding to logic value 0, the 2B output node out2B is complementarily in a state corresponding to logic value 1. Therefore, when the setting of the first step is performed, a high current flows from the 2B output node out2B toward the CBLB node through the 2B MRAM cell 530B due to the high voltage potential difference between the 2B output node out2B and the CBLB node, and the MTJRB enters a low resistance state due to the high current.

As described above, as a result of performing the first step, the first voltage (e.g., a low voltage of 0V) is applied to the CBLB node, and a resistance state indicating the corresponding output value is formed in one of the two MTJs between MTJLB and MTJRB.
Second step: When performing the setting of the second step after a low resistance state is formed in one of the MTJs between MTJLB and MTJRB by the operation in the first step, the controller 440 performs the operation of applying a second voltage (i.e., a high voltage Vdd) having a complementary level to the first voltage to the CBLB node. In this case, the controller 440 performs the setting of the second step by maintaining the ON signals for the gates of the 1B selection transistor M7B and the 2B selection transistor M8B and the OFF signals for the gates of the 1B access transistor M5B and the 2B access transistor M6B in their previous input states.

When the setting of the second step is performed and the 1B output node out1B is in a state corresponding to logic value 1 (e.g., a high voltage Vdd state), a potential difference sufficient to cause a high current to flow through the 1B MRAM cell 520B is not generated between the 1B output node out1B and the CBLB node; therefore, the state of the MTJLB is maintained in its previous state.

When the 1B output node out1B is in a state corresponding to logic value 1, the 2B output node out2B enters a complementary state corresponding to logic value 0 (e.g., 0V state). Therefore, when the setting of the second step is performed, a potential difference sufficient to cause a high current to flow from the CBLB node toward the 2B output node out2B is generated in the 2B MRAM cell 530B.

Accordingly, when the setting of the second step is performed, a reverse high current flows into the 2B MRAM cell 530B due to the high voltage between the 2B output node out2B and the CBLB node, and the MTJRB within the 2B MRAM cell 530B enters a high resistance state due to the high current.

When the 1B output node out1B is in a state corresponding to logic value 0 (e.g., 0V state), a potential difference between the 1B output node out1B and the CBLD node sufficient to cause a high current to flow from the CBLB node toward the 1B output node out1B is generated in the 1B MRAM cell 520B.

Accordingly, a reverse high current flows into the 1B MRAM cell 520B due to the high voltage between the 1B output node out1B and the CBLB node, and the MTJLB within the 1B MRAM cell 520B enters a high resistance state due to the high current. As described above, in the second step, when the second voltage (e.g., a high voltage) is applied to the CBLB node, one of the MTJs between the MTJLB and the MTJRB enters a high resistance state indicating the corresponding output value, thereby completing the second step and consequently completing the setting of the MTJ value.

Meanwhile, the gate of the first selection transistor M7 and the gate of the 1B selection transistor M7B may be connected to each other so that the CWLL signal may be input simultaneously, and the gate of the second selection transistor M8 and the gate of the 2B selection transistor M8B may be connected to each other so that the CWLR signal may be input simultaneously.

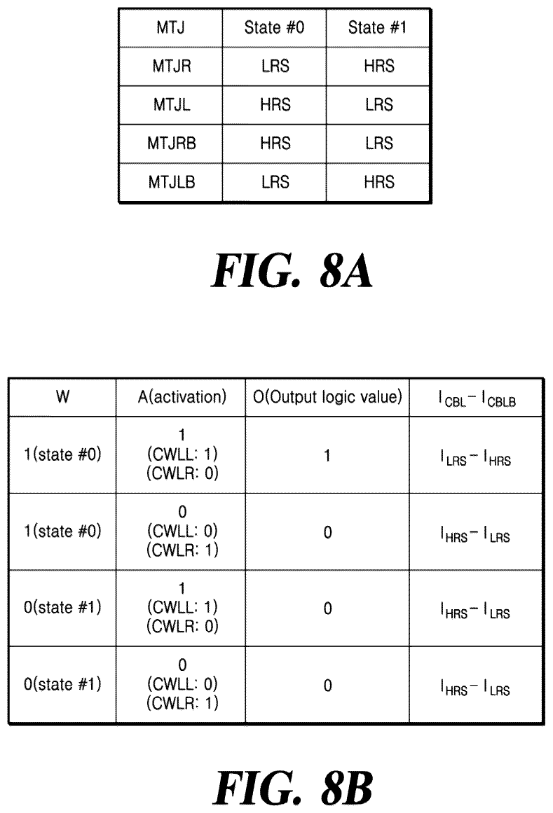

FIG. 8a illustrates the states of four MTJs after the step of setting MTJ values is completed in a 16T4R nvSRAM, and FIG. 8b illustrates a truth table of operation in the 16T4R nvSRAM and the corresponding current values.

As shown in FIG. 8a, the four MTJs have two states (i.e., state #0 and state #1). In state #0, the resistance states of MTJR, MTJL, MTJRB, and MTJLB are LRS, HRS, HRS, and LRS, respectively, while in state #1, the resistance states of MTJR, MTJL, MTJRB, and MTJLB are HRS, LRS, LRS, and HRS, respectively. In other words, the write input and the complementary write input are applied so that the resistance states of the four MTJs are set to state #0 or state #1.

MTJR has a complementary resistance state to MTJL, MTJRB has a complementary state to MTJR, and MTJLB has a complementary resistance state to MTJRB. Therefore, MTJL and MTJRB have the same resistance state.

FIG. 8b illustrates a truth table of operation in the 16T4R nvSRAM and the corresponding current values.

In FIG. 8b, W denotes the resistance states of four MTJs and the corresponding logic values in the 16T4R structure, A denotes the input value of the activation signal, and O denotes the result of the computation A×W.

Also, I_{CBL}−I_{CBLB} denotes the current value detected by a current circuit (not shown) within the controller 440 in relation to the corresponding 16T4R nvSRAM cell.

For each 16T4R nvSRAM cell, a current circuit (not shown) within the controller 440 receives the CBL current I_{CBL} flowing from the CBL node and the CBLB current I_{CBLB} flowing from the CBLB node and then obtains I_{CBL}−I_{CBLB}. Here, the current value detected by the current circuit (not shown) refers to the value obtained by subtracting the current I_{CBLB} flowing from the CBLB node from the current I_{CBL} flowing from the CBL node.

As shown in FIG. 8b, when 0 (the output logic value) is 1, the current value of the corresponding nvSRAM cell in the current circuit (not shown) is I_{LRS}−I_{HRS}, and when 0 (the output logic value) is 0, the current value of the corresponding nvSRAM cell in the current circuit (not shown) is I_{HRS}−I_{LRS}.

As shown in FIG. 8b, regardless of the output logic value, all nvSRAM cells 410, 420, 430 included in the computation apparatus 400 are activated and interconnected in parallel. Therefore, the composite resistance due to the activated nvSRAM cells 410, 420, 430 becomes constant.

Accordingly, in the 16T4R nvSRAM structure, the number of activated nvSRAM cells 410, 420, 430 does not affect the magnitude of the voltage detected by the voltage conversion circuit.

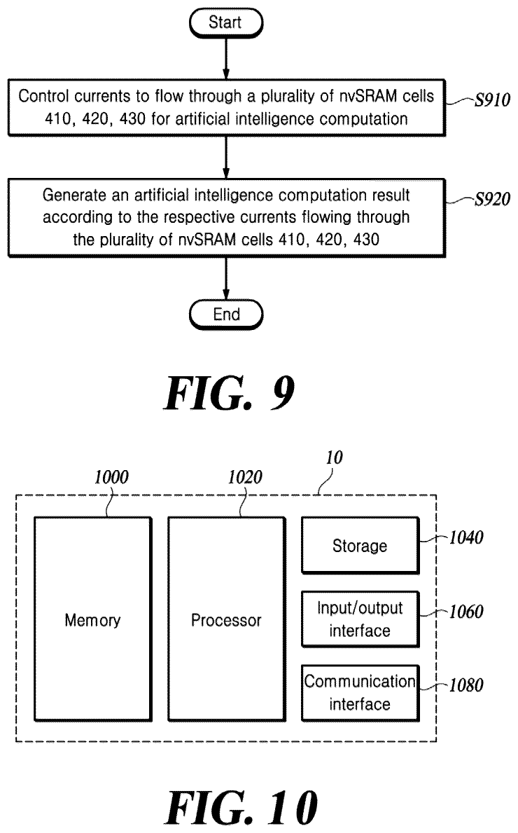

FIG. 9 is a flowchart illustrating a computation method according to an embodiment of the present disclosure.

The computation method according to the present embodiment is performed by the computation apparatus 400 according to the present embodiment.

The controller 440 performs a first process S910 of controlling current to flow through each of a plurality of nvSRAM cells 410, 420, 430 for artificial intelligence computation.

The controller 440 performs a second process S920 of generating an artificial intelligence computation result according to the respective currents flowing through the plurality of nvSRAM cells 410, 420, 430.

FIG. 10 is a block diagram illustrating an exemplary computing device that may be used to implement a method or an apparatus according to the present disclosure.

The computing device 10 may include all or part of a memory 1000, a processor 1020, storage 1040, an input/output interface 1060, and a communication interface 1080. The computing device 10 may be a stationary computing device, such as a desktop computer or a server, as well as a mobile computing device, such as a laptop computer, a smartphone, or an automotive electronic device. The computing device 10 may be implemented as an arbitrarily specialized hardware accelerator capable of efficiently processing operations devised for an artificial intelligence model. For example, the computing device 10 may include a graphics processing unit (GPU), a Tensor Processing Unit (TPU), or a neural processing unit (NPU).

The memory 1000 may store a program that enables the processor 1020 to perform methods or operations according to various embodiments of the present disclosure. For example, a program may include a plurality of instructions executable by the processor 1020, and the method illustrated in FIG. 9 may be performed by executing the plurality of instructions by the processor 1020. The memory 1000 may consist of a single memory or a plurality of memories. In this case, information required to perform the methods or operation according to various embodiments of the present disclosure may be stored in a single memory or distributed across a plurality of memories. When the memory 1000 is composed of a plurality of memories, the plurality of memories may be physically separated. The memory 1000 may include at least one of volatile memory and non-volatile memory. Volatile memory includes Static Random Access Memory (SRAM) or Dynamic Random Access Memory (DRAM), while non-volatile memory includes flash memory.

The processor 1020 may include at least one core capable of executing at least one instruction. The processor 1020 may execute instructions stored in the memory 1000. The processor 1020 may consist of a single processor or a plurality of processors.

The storage 1040 maintains stored data even if power supplied to the computing device 10 is cut off. For example, the storage 1040 may include non-volatile memory or may include a storage medium such as a magnetic tape, an optical disk, or a magnetic disk. A program stored in the storage 1040 may be loaded into the memory 1000 before being executed by the processor 1020. The storage 1040 may store files written in a program language, and a program created from the files by a compiler may be loaded into the memory 1000. The storage 1040 may store data to be processed by the processor 1020 and/or data processed by the processor 1020.

The input/output interface 1060 may include an input device such as a keyboard, a mouse, a touch display, or a microphone and an output device such as a display or a speaker. The user may trigger execution of a program by the processor 1020 and/or check the processing results of the processor 1020 through the input/output interface 1060.

The communication interface 1080 may provide access to an external network. The computing device 10 may communicate with other devices through the communication interface 1080.

The components described in the example embodiments may be implemented by hardware components including, for example, at least one digital signal processor (DSP), a processor, a controller, an application-specific integrated circuit (ASIC), a programmable logic element, such as an FPGA, other electronic devices, or combinations thereof. At least some of the functions or the processes described in the example embodiments may be implemented by software, and the software may be recorded on a recording medium. The components, the functions, and the processes described in the example embodiments may be implemented by a combination of hardware and software.

The method according to example embodiments may be embodied as a program that is executable by a computer, and may be implemented as various recording media such as a magnetic storage medium, an optical reading medium, and a digital storage medium.

Various techniques described herein may be implemented as digital electronic circuitry, or as computer hardware, firmware, software, or combinations thereof. The techniques may be implemented as a computer program product, i.e., a computer program tangibly embodied in an information carrier, e.g., in a machine-readable storage device (for example, a computer-readable medium) or in a propagated signal for processing by, or to control an operation of a data processing apparatus, e.g., a programmable processor, a computer, or multiple computers. A computer program(s) may be written in any form of a programming language, including compiled or interpreted languages and may be deployed in any form including a stand-alone program or a module, a component, a subroutine, or other units suitable for use in a computing environment. A computer program may be deployed to be executed on one computer or on multiple computers at one site or distributed across multiple sites and interconnected by a communication network.

Processors suitable for execution of a computer program include, by way of example, both general and special purpose microprocessors, and any one or more processors of any kind of digital computer. Generally, a processor will receive instructions and data from a read-only memory or a random access memory or both. Elements of a computer may include at least one processor to execute instructions and one or more memory devices to store instructions and data. Generally, a computer will also include or be coupled to receive data from, transfer data to, or perform both on one or more mass storage devices to store data, e.g., magnetic, magneto-optical disks, or optical disks. Examples of information carriers suitable for embodying computer program instructions and data include semiconductor memory devices, for example, magnetic media such as a hard disk, a floppy disk, and a magnetic tape, optical media such as a compact disk read only memory (CD-ROM), a digital video disk (DVD), etc. and magneto-optical media such as a floptical disk, and a read only memory (ROM), a random access memory (RAM), a flash memory, an erasable programmable ROM (EPROM), and an electrically erasable programmable ROM (EEPROM) and any other known computer readable medium. A processor and a memory may be supplemented by, or integrated into, a special purpose logic circuit.

The processor may run an operating system (OS) and one or more software applications that run on the OS. The processor device also may access, store, manipulate, process, and create data in response to execution of the software. For purpose of simplicity, the description of a processor device is used as singular; however, one skilled in the art will be appreciated that a processor device may include multiple processing elements and/or multiple types of processing elements. For example, a processor device may include multiple processors or a processor and a controller. In addition, different processing configurations are possible, such as parallel processors.

Also, non-transitory computer-readable media may be any available media that may be accessed by a computer, and may include both computer storage media and transmission media.

The present specification includes details of a number of specific implements, but it should be understood that the details do not limit any invention or what is claimable in the specification but rather describe features of the specific example embodiment. Features described in the specification in the context of individual example embodiments may be implemented as a combination in a single example embodiment. In contrast, various features described in the specification in the context of a single example embodiment may be implemented in multiple example embodiments individually or in an appropriate sub-combination. Furthermore, the features may operate in a specific combination and may be initially described as claimed in the combination, but one or more features may be excluded from the claimed combination in some cases, and the claimed combination may be changed into a sub-combination or a modification of a sub-combination.

Similarly, even though operations are described in a specific order on the drawings, it should not be understood as the operations needing to be performed in the specific order or in sequence to obtain desired results or as all the operations needing to be performed. In a specific case, multitasking and parallel processing may be advantageous. In addition, it should not be understood as requiring a separation of various apparatus components in the above described example embodiments in all example embodiments, and it should be understood that the above-described program components and apparatuses may be incorporated into a single software product or may be packaged in multiple software products.

It should be understood that the example embodiments disclosed herein are merely illustrative and are not intended to limit the scope of the invention. It will be apparent to one of ordinary skill in the art that various modifications of the example embodiments may be made without departing from the spirit and scope of the claims and their equivalents.

Accordingly, one of ordinary skill would understand that the scope of the claimed invention is not to be limited by the above explicitly described embodiments but by the claims and equivalents thereof.

What is claimed is:

1. A computation apparatus comprising:
a plurality of nvSRAM cells; and
a controller configured to generate an artificial intelligence computation result according to currents flowing through the plurality of nvSRAM cells,
wherein each nvSRAM cell comprises a first partial cell, and
the first partial cell comprises:
a differential circuit including a first inverter and a second inverter connected in parallel between a power supply voltage and a ground voltage, a first output node of the first inverter being connected to a second input node of the second inverter and a second output node of the second inverter being connected to a first input node of the first inverter;
a first access transistor having a drain connected to the first output node;
a second access transistor having a drain connected to the second output node;
a first MRAM cell including a first selection transistor and a first magnetic tunnel junction connected in series between a CBL node and the first output node; and
a second MRAM cell including a second selection transistor and a second magnetic tunnel junction connected in series between the CBL node and the second output node.

2. The apparatus of claim 1, wherein the controller is configured to input OFF signals to the gates of the first selection transistor and the second selection transistor, respectively; ON signals to the gates of the first access transistor and the second access transistor, respectively; and a write signal to the source of the first access transistor and a complementary write signal to the source of the second access transistor, thereby forming a first output value at the first output node based on the write signal.

3. The apparatus of claim 1, wherein the controller is configured to input ON signals to the gates of the first selection transistor and the second selection transistor, respectively; input OFF signals to the gates of the first access transistor and the second access transistor, respectively; and form complementary resistance states in the first magnetic tunnel junction and the second magnetic tunnel junction, respectively, by alternately inputting a low voltage and a high voltage to the CBL node at an interval equal to or greater than a predetermined interval.

4. The apparatus of claim 1, wherein the controller is configured to input OFF signals to the gates of the first selection transistor and the second selection transistor, respectively; input ON signals to the gates of the first access transistor and the second access transistor, respectively; and form a resistance state in one of magnetic tunnel junctions between the first magnetic tunnel junction and the second magnetic tunnel junction by applying a first low voltage to the CBL node and
a resistance state in the other magnetic tunnel junction between the first magnetic tunnel junction and the second magnetic tunnel junction by applying a second low voltage complementary to the first voltage to the CBL node after the resistance state is formed in the one magnetic tunnel junction.

5. The apparatus of claim 4, wherein, when the first voltage is a low voltage, a resistance state of one of the first magnetic tunnel junction and the second magnetic tunnel junction is formed as a low-resistance state, and
when the first voltage is a high voltage, a resistance state of the other one of the first magnetic tunnel junction and the second magnetic tunnel junction is formed as a high-resistance state.

6. The apparatus of claim 5, wherein, when the first voltage is a low voltage, a resistance state of the one of the first magnetic tunnel junction and the second magnetic tunnel junction is kept to its previous state, and
when the first voltage is a high voltage, a resistance state of the other one of the first magnetic tunnel junction and the second magnetic tunnel junction is kept to its previous state.

7. The apparatus of claim 1, wherein, when ON signals are applied to the gates of the first selection transistor and the second selection transistor, respectively, and signals having complementary values are applied to the gates of the first access transistor and the second access transistor, respectively, the controller is configured to generate a computation result according to the current flowing from the CBL node.

8. The apparatus of claim 7, wherein the controller is configured to receive respective currents flowing from the CBL node of each nvSRAM cell and to generate the computation result according to a result obtained by summing the magnitudes of the respective currents.

9. The apparatus of claim 1, further including a second partial cell,
wherein the second partial cell comprises:
a second differential circuit including a 1B inverter and a 2B inverter connected in parallel between a power supply voltage and a ground voltage, a 1B output node of the 1B inverter being connected to a 2B input node of the 2B inverter and a 2B output node of the 2B inverter being connected to a 1B input node of the 1B inverter;
a 1B access transistor having a drain connected to the 1B output node;
a 2B access transistor having a drain connected to the 2B output node;
a 1B MRAM cell including a 1B selection transistor and a 1B magnetic tunnel junction connected in series between a CBLB node and the 1B output node; and
a 2B MRAM cell including a 2B selection transistor and a 2B magnetic tunnel junction connected in series between the CBLB node and the 2B output node.

10. The apparatus of claim 9, wherein the first magnetic tunnel junction and the 1B magnetic tunnel junction are set to complementary states, the first magnetic tunnel junction and the second magnetic tunnel junction are set to complementary states, and the second magnetic tunnel junction and the 2B magnetic tunnel junction are set to complementary states.

11. The apparatus of claim 9, wherein the controller is configured to receive, for each nvSRAM cell, a CBL current flowing from the CBL node and a CBLB current flowing from the CBLB node, compute a difference value between the CBL current and the CBLB current, and generate the computation result according to a sum of the difference values corresponding to the respective nvSRAM cells.

12. A method for performing computation in a computation apparatus comprising a plurality of nvSRAM cells, wherein each nvSRAM cell comprises a first partial cell, and the first partial cell comprises a differential circuit including a first inverter and a second inverter connected in parallel between a power supply voltage and a ground voltage, a first output node of the first inverter being connected to a second input node of the second inverter and a second output node of the second inverter being connected to a first input node of the first inverter; a first access transistor having a drain connected to the first output node; a second access transistor having a drain connected to the second output node; a first MRAM cell including a first selection transistor and a first magnetic tunnel junction connected in series between a CBL node and the first output node; and a second MRAM cell including a second selection transistor and a second magnetic tunnel junction connected in series between the CBL node and the second output node, the method comprising:
a first process of controlling current to flow through each of the plurality of nvSRAM cells for artificial intelligence computation; and
a second process of generating the artificial intelligence computation result according to the respective currents flowing through the plurality of nvSRAM cells.

13. The method of claim 12, wherein the first process inputs OFF signals to the gates of the first selection transistor and the second selection transistor, respectively; ON signals to the gates of the first access transistor and the second access transistor, respectively; and a write signal to the source of the first access transistor and a complementary write signal to the source of the second access transistor, thereby forming a first output value at the first output node based on the write signal.

14. The method of claim 12, wherein the first process inputs ON signals to the gates of the first selection transistor and the second selection transistor, respectively; inputs OFF signals to the gates of the first access transistor and the second access transistor, respectively; and forms complementary resistance states in the first magnetic tunnel junction and the second magnetic tunnel junction, respectively, by alternately inputting a low voltage and a high voltage to the CBL node at an interval equal to or greater than a predetermined interval.

15. The method of claim 12, wherein the first process inputs OFF signals to the gates of the first selection transistor and the second selection transistor, respectively; inputs ON signals to the gates of the first access transistor and the second access transistor, respectively; and forms a resistance state in one of magnetic tunnel junctions between the first magnetic tunnel junction and the second magnetic tunnel junction by applying a first low voltage to the CBL node and
a resistance state in the other magnetic tunnel junction between the first magnetic tunnel junction and the second magnetic tunnel junction by applying a second low voltage complementary to the first voltage to the CBL node after the resistance state is formed in the one magnetic tunnel junction.

16. The method of claim 15, wherein, when the first voltage is a low voltage, a resistance state of one of the first magnetic tunnel junction and the second magnetic tunnel junction is formed as a low-resistance state, and
when the first voltage is a high voltage, a resistance state of the other one of the first magnetic tunnel junction and the second magnetic tunnel junction is formed as a high-resistance state.

17. The method of claim 12, wherein, when ON signals are applied to the gates of the first selection transistor and the second selection transistor, respectively, and signals having complementary values are applied to the gates of the first access transistor and the second access transistor, respectively, a computation result is generated according to the current flowing from the CBL node.

18. The method of claim 17, wherein the second process receives respective currents flowing from the CBL node of each nvSRAM cell and generates the computation result according to a result obtained by summing the magnitudes of the respective currents.

19. The method of claim 12, wherein the computation apparatus further includes a second partial cell,
wherein the second partial cell comprises:
a second differential circuit including a 1B inverter and a 2B inverter connected in parallel between a power supply voltage and a ground voltage, a 1B output node of the 1B inverter being connected to a 2B input node of the 2B inverter and a 2B output node of the 2B inverter being connected to a 1B input node of the 1B inverter;
a 1B access transistor having a drain connected to the 1B output node;
a 2B access transistor having a drain connected to the 2B output node;
a 1B MRAM cell including a 1B selection transistor and a 1B magnetic tunnel junction connected in series between a CBLB node and the 1B output node; and
a 2B MRAM cell including a 2B selection transistor and a 2B magnetic tunnel junction connected in series between the CBLB node and the 2B output node.

20. The method of claim 19, wherein the second process receives, for each nvSRAM cell, a CBL current flowing from the CBL node and a CBLB current flowing from the CBLB node, computes a difference value between the CBL current and the CBLB current, and generates the computation result according to a sum of the difference values corresponding to the respective nvSRAM cells.
